(19) United States
(12) Patent Application Publication
(10) Pub. No.: US 2007/0241740 A1
(43) Pub. Date: Oct. 18, 2007

(54) Hand-Held Probe

(75) Inventor: Julian Richard Hawes, Oxford (GB)

Correspondence Address: WORKMAN NYDEGGER, 60 EAST SOUTH TEMPLE, 1000 EAGLE GATE TOWER, SALT LAKE CITY, UT, 84111, US

(73) Assignee: United Kingdom Atomic Energy Authority, Oxford (GB)

(21) Appl. No.: 11/570,586

(22) PCT Filed: Jun. 13, 2005
(86) PCT No.: PCT/GB05/02314

§ 371 Date: Dec. 13, 2006

(30) Foreign Application Priority Data
Jun. 19, 2004 (GB) 0413746.9

(51) Int. Cl. G01R 1/067

(52) U.S. Cl. 324/149; 73/146.8

(57) ABSTRACT

A handheld probe comprises means for sensing a physical property such as current, voltage, temperature and pressure by locating the probe in contact with an article or in close proximity to an article, a battery for alimenting the probe, and means for wirelessly transmitting sensed data from the probe to a display unit spaced from the probe.

### FIELD OF THE INVENTION

The invention relates to hand-held probes for sensing a physical property such as current, voltage, temperature and pressure.

### BACKGROUND TO THE INVENTION AND PRIOR ART KNOWN TO THE APPLICANT(S)

One form of prior art known to the applicants is an electrical thermometer which incorporates a sensing portion and a display panel as part of the actual thermometer. Other conceptually similar hand-held probes exist where displays are literally part of the hand-held probe such as certain tire pressure gauges. Due to the reduced size of these probes, their display units, which are part of the probes themselves, are by definition, limited in their display capacity and their range of displayed information. When extensive information is to be displayed, hand-held probes are usually wired to a display unit which often comprises relatively bulky processing means necessary to display the information. The articles from which a physical property is to be ascertained are sometimes difficult for a user to, during the sensor operation, read the display unit when the display unit is located on the probe itself. This is the case for example for tire pressure gauges which incorporate display units on the hand-held probe.

### SUMMARY OF THE INVENTION

In its broadest aspect, the invention provides a hand-held probe comprising means for sensing a physical property such as current, voltage, temperature and pressure by locating the probe in contact with an article or in close proximity to an article, a battery for alimenting the probe and means for wirelessly transmitting sensed data from the probe to a display unit spaced from the probe.

This configuration is particularly advantageous because it allows display units to display more advanced information because it may more easily incorporate advanced electronics than the electronics that would have to fit within the hand-held probe itself. It also allows the display unit to be located where the operator can access the information with greater ease even in real time if necessary. A single hand-held probe may also be readily programmed to operate in conjunction with different bespoke processing means for displaying different specific physical properties. It also simplifies the overall operation of sensing the physical property because an operator will not have to know how to wire the display unit with a given hand-held probe. Once a hand-held probe and an appropriate display unit are activated, the sensing operation may be initiated without wasteful set up time.

In a subsidiary aspect in accordance with the invention's broadest independent aspect, the probe also incorporates means for scanning the article tested in order to identify the kind of article which is being tested. This would allow a hand-held probe and display unit combination to more easily be adapted for use with a variety of different articles without requiring complex set up operations.

In a further subsidiary aspect, the probe incorporates processing means which adapt the display dependent on the kind of article being tested. This allows the probe to be used on a variety of articles without unduly complex set up operations.

In a further subsidiary aspect, the probe farther comprises a delay memory buffer. This would allow transmissions to occur at high frequencies without either unduly draining the battery or exceeding the probe's onboard capacity.

In a further subsidiary aspect, the probe incorporates a tire valve attachment means and a pressure sensor and the display unit also being a wireless unit which can be hand-held. This would allow pressure to be sensed without requiring a user to either bend down close to the tire or have to repeatedly twist around to read a display unit located behind the user. This allows pressure to be assessed with greater ease and efficiency.

### BRIEF DESCRIPTION OF THE FIGURES

FIG. 1 shows a representation of a hand-held probe with a display unit in accordance with a first embodiment of the invention.

FIG. 2 shows a hand-held probe with a barcode scanner in accordance with a second embodiment of the invention.

FIG. 3 shows a hand-held probe for measuring the pressure on tires with an associated display unit in accordance with a third embodiment of the invention.

### DETAILED DESCRIPTION OF THE FIGURES

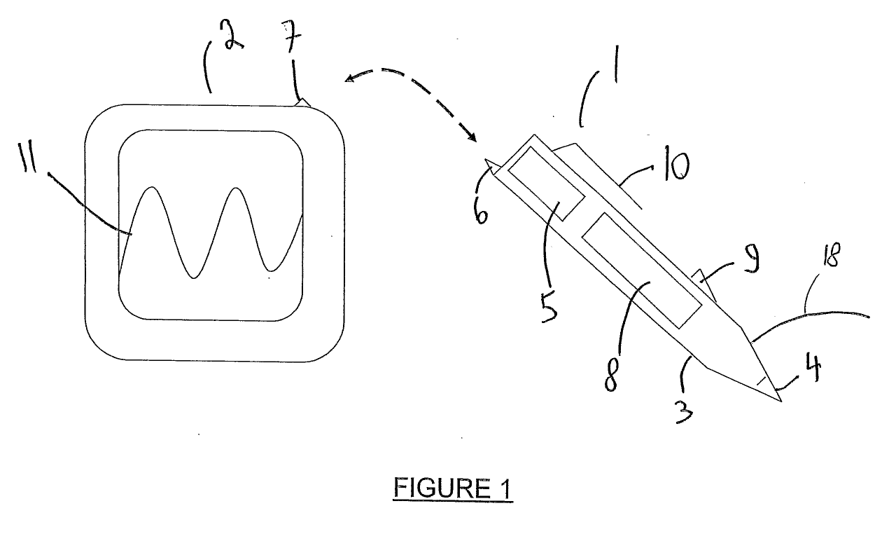

FIG. 1 shows a hand-held probe 1 equipped for wirelessly transmitting data to a display unit 2. The wireless transmission may be selected to take several forms such as infra-red, Blue Tooth or any other wireless transmission means appropriately selected by the person skilled in the art. Wireless probe 1 takes the form of a pen with an isolating sheath 3. At its lower extremity, a metallic contact 4 protrudes from the sheath 3. A so called flying lead referenced 18 is used for connecting to part of the circuit under test which can act as a reference. Processing means 5 located within the sheath 3 are in communication with contact 4. In use, contact 4 may be placed against a part of an electric circuit through which current flows. Current data (or voltage and resistance values) is then preferably transmitted in real time between transmitter 6 and receiver 7. Processing means 5 may also incorporate a memory buffer if necessary for certain forms of transmission.

The probe may be powered by a battery 8 located inside the sheath 3. An on/off button 9 may be provided as part of the hand-held probe. The invention also envisages that the display unit may incorporate processing means which could switch the hand-held probe on and off without requiring the provision of such an on/off switch. A clip 10 may be incorporated on the hand-held probe for securing the probe to an operator's shirt pocket if appropriate. An indicator for informing an operator of the on or off state of the hand-held probe may be incorporated if necessary. A recharging port (not illustrated in the figure) may also be provided. The invention also envisages that the metal contact 4 may be adapted for charging the battery by employing circuitry which differentiate between recharging mode and sensing mode.

The processing means located inside the sheath may be multilayered for compactness.

The display unit 2 (such as a computer or a part of a computer) may have a screen for displaying changes in current as shown by curve 11 in the figure.

The display unit may incorporate processing means for the operator to modify the displays to, for example, voltages etc. The display unit may also simply be a storage means from which data may be extracted by an operator and then appropriately displayed for assessment.

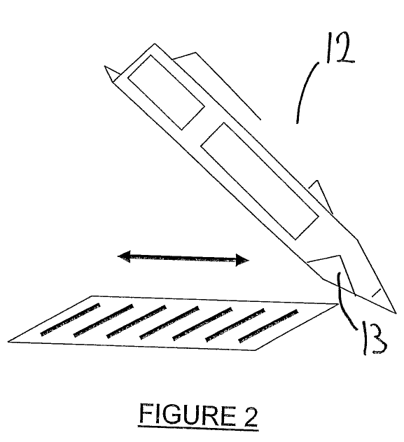

FIG. 2 shows a hand-held probe 12 of the kind described above with reference to FIG. 1 but with the addition of a barcode scanner 13. By scanning the probe across a barcode, being an appropriate identifier for the apparatus to be measured, the identification of the apparatus may be used to display more specific information which may be useful to the operator of the probe.

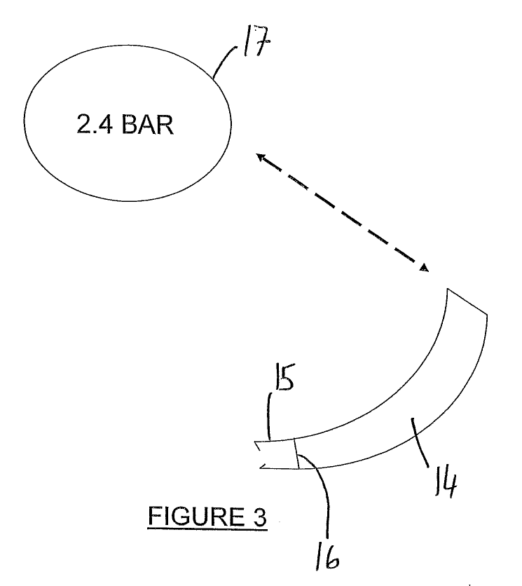

FIG. 3 shows a hand-held probe 14 which would incorporate a battery, a transmitter and processing means in a similar fashion to the hand-held probes described with reference to FIGS. 1 and 2. Hand-held probe 14 would however incorporate a portion 15 capable of clipping onto a tire valve and a pressure sensor 16. The pressure data measured could then be transmitted wirelessly to a receiving display unit 17 which would display a pressure value such as 2.4 BAR. The display unit may be itself powered by a rechargeable battery so that both hand-held probe and the display unit may be wireless for maximum system flexibility. The display unit may incorporate releasable attachment means such as a magnetic strip to attach the display unit to the body of a motor vehicle so that measuring the pressure of a vehicle tire may be a one handed operation if needs be.

1. A handheld probe, comprising a sensor for sensing a physical property such as current, voltage, temperature and pressure by locating the probe in contact with an article or in close proximity to an article, a battery for alimenting the probe, and a transmitter for wirelessly transmitting sensed data from the probe to a display unit spaced from the probe.

2. A handheld probe according to claim 1, wherein the probe also incorporates means a scanner for scanning the article tested in order to identify the kind of article which is being tested.

3. A handheld probe according to claim 2, wherein the probe incorporates a processor which adapts the display dependent on the kind of article being tested.

4. A handheld probe according to claim 1, wherein the probe further comprises a delay memory buffer.

5. A handheld probe according to claim 1, wherein the probe incorporates a tire valve attachment means and a pressure sensor, and the display unit also being a wireless unit which can be handheld.

6. (canceled)
